(19) United States
(12) Patent Application Publication
(10) Pub. No.: US 2025/0212364 A1
(43) Pub. Date: Jun. 26, 2025

(54) HEAT DISSIPATION REGULATION SYSTEM

(71) Applicant: BITMAIN TECHNOLOGIES INC., Beijing (CN)

(72) Inventors: Tianhao LI, Beijing (CN); Hangkong Hu, Beijing (CN); Xiaoxiong Zhang, Beijing (CN); Fengjie Li, Beijing (CN); Wenkai Cui, Beijing (CN); Yongbo Ge, Beijing (CN); Hongshan Zhu, Beijing (CN); Shaoming Huang, Beijing (CN); Jinquan Xie, Beijing (CN)

(21) Appl. No.: 19/002,079

(22) Filed: Dec. 26, 2024

(30) Foreign Application Priority Data
Dec. 25, 2023 (CN) 202311799539.3

(51) Int. Cl. H05K 7/20

(52) U.S. Cl. CPC H05K 7/20281; H05K 7/20272

(57) ABSTRACT

The present disclosure provides a heat dissipation regulation system. The system includes a first temperature acquisition unit configured to collect an outlet water temperature of a water outlet of a heat absorption unit; a second temperature acquisition unit configured to collect an inlet water temperature of a water inlet of the heat absorption unit; a flow rate measurement unit configured to measure flow rate of circulating cooling water flowing in or out of the heat absorption unit; a circulating water pipeline including a temperature-stabilizing water branch pipeline and a cooling water branch pipeline connected in parallel between the water inlet and the water outlet of the heat absorption unit; a plurality of regulating valves, arranged in the temperature-stabilizing water branch pipeline and the cooling water branch pipeline, respectively; a controller, electrically connected with the first temperature acquisition unit, the second temperature acquisition unit and the plurality of regulating valves.

### CROSS-REFERENCE TO RELATED APPLICATION

This application claims priority to Chinese Patent Application No. 202311799539.3, filed on Dec. 25, 2023, which is hereby incorporated by reference in its entirety.

### TECHNICAL FIELD

The present disclosure relates to the fields of heat dissipation technology, cloud computing technology and Internet of Things technology, and in particular to a heat dissipation regulation system.

### BACKGROUND

With the rapid development of informatization, the rise of industries such as artificial intelligence, cloud computing and the Internet of Things, the construction of large-scale data centers has shown a rapid growth trend. In order to meet the demands, data centers need to be equipped with large or numerous network devices for data processing and storage, which causes the data centers to generate a lot heat. To ensure stable operations of various network devices within the data centers, it is necessary to dissipate the heat generated by the data centers in time.

### SUMMARY

In view of the above, the present disclosure provides a heat dissipation regulation system, including: a first temperature acquisition unit configured to collect an outlet water temperature of a water outlet of a heat absorption unit, where the heat absorption unit is configured to absorb, by using circulating cooling water flowing through the heat absorption unit, heat generated by a heat dissipation device; a second temperature acquisition unit configured to collect an inlet water temperature of a water inlet of the heat absorption unit; a flow rate measurement unit configured to measure flow rate of the circulating cooling water flowing in or out of the heat absorption unit; a circulating water pipeline including a temperature-stabilizing water branch pipeline and a cooling water branch pipeline, where the temperature-stabilizing water branch pipeline and the cooling water branch pipeline are connected in parallel between the water inlet and the water outlet of the heat absorption unit; a plurality of regulating valves, arranged in the temperature-stabilizing water branch pipeline and the cooling water branch pipeline, respectively; a controller, electrically connected with the first temperature acquisition unit, the second temperature acquisition unit and the plurality of regulating valves, and configured to regulate opening degrees of the plurality of regulating valves according to the outlet water temperature, the inlet water temperature, the flow rate, and heating demand information.

According to an embodiment of the present disclosure, the controller being configured to adjust the opening degrees of the plurality of regulating valves according to the outlet water temperature, the inlet water temperature, the flow rate, and the heating demand information, includes: determining a target regulating valve from the plurality of regulating valves according to the outlet water temperature, the inlet water temperature, the flow rate, and the heating demand information sent by a user terminal; closing regulating valves other than the target regulating valve among the plurality of regulating valves; and adjusting an opening degree of the target regulating valve.

According to an embodiment of the present disclosure, the above-mentioned system further includes a heat exchange unit arranged in the cooling water branch pipeline, and configured to recover heat absorbed by the heat absorption unit; where the cooling water branch pipeline includes: a first cooling water branch pipeline and a second cooling water branch pipeline; the heat exchange unit includes: a heat exchanger arranged in the first cooling water branch pipeline and a dry cooler arranged in the second cooling water branch pipeline; and the plurality of regulating valves include: a first regulating valve arranged in the temperature-stabilizing water branch pipeline, a second regulating valve arranged in the first cooling water branch pipeline, and a third regulating valve arranged in the second cooling water branch pipeline.

According to an embodiment of the present disclosure, the controller being configured to determine the target regulating valve from the plurality of regulating valves according to the outlet water temperature, the inlet water temperature, the flow rate and the heating demand information, includes: determining flow temperature difference heat according to the outlet water temperature, the inlet water temperature and the flow rate; obtaining a predetermined maximum heat dissipation of the heat exchanger; in a case where the flow temperature difference heat is greater than or equal to a predetermined maximum heat dissipation and a heating demand is determined to be present according to the heating demand information, determining each of the second regulating valve and the third regulating valve as the target regulating valve.

According to an embodiment of the present disclosure, the controller being configured to adjust the opening degree of the target regulating valve includes: in a case where the inlet water temperature is greater than a target inlet water temperature, reducing an opening degree of the second regulating valve and increasing an opening degree of the third regulating valve; in a case where the inlet water temperature is lower than a first temperature and this state lasts for a first preset duration, stopping adjusting the opening degree of the second regulating valve and the opening degree of the third regulating valve, where the first temperature is equal to a sum of the target inlet water temperature and a first preset value.

According to an embodiment of the present disclosure, the controller being configured to adjust the opening degree of the target regulating valve further includes: in a case where the inlet water temperature is greater than or equal to the first temperature and this state lasts for a second preset duration, stopping adjusting the opening degree of the second regulating valve and the opening degree of the third regulating valve and increasing an operating frequency of the dry cooler; in a case where the operating frequency of the dry cooler is less than a first predetermined frequency, the inlet water temperature is less than the first temperature, and this state lasts for the second preset duration, stopping adjusting the operating frequency of the dry cooler.

According to an embodiment of the present disclosure, the controller being configured to adjust the opening degree of the target regulating valve further includes: in a case where the operating frequency of the dry cooler is greater than or equal to the first predetermined frequency, the inlet water temperature is greater than or equal to the first temperature, and this state lasts for a third preset duration, stopping adjusting the operating frequency of the dry cooler, reducing the opening degree of the second regulating valve, and increasing an opening degree of the third regulating valve; in a case where the inlet water temperature is less than or equal to a second temperature and this state lasts for the third preset duration, stopping adjusting the opening degree of the second regulating valve and the opening degree of the third regulating valve, and reducing the operating frequency of the dry cooler; where the second temperature is equal to a sum of the target inlet water temperature and a second preset value; in a case where the operating frequency of the dry cooler is greater than a second predetermined frequency, the inlet water temperature is greater than the second temperature and less than the first temperature, and this state lasts for the third preset duration, stopping adjusting the operating frequency of the dry cooler.

According to an embodiment of the present disclosure, the controller being configured to determine the target regulating valve from the plurality of regulating valves according to the outlet water temperature, the inlet water temperature, the flow rate and the heating demand information, further includes: in a case where the flow temperature difference heat is less than the predetermined maximum heat dissipation, and a heating demand is determined to be present according to the heating demand information, determining each of the first regulating valve and the second regulating valve as the target regulating valve.

According to an embodiment of the present disclosure, the controller being configured to adjust the opening degree of the target regulating valve includes: in a case where the inlet water temperature is less than or equal to a second temperature and this state lasts for a fourth preset duration, reducing an opening degree of the second regulating valve and increasing an opening degree of the first regulating valve; in a case where the inlet water temperature is greater than the second temperature and less than a first temperature, and this state lasts for the fourth preset duration, stopping adjusting the opening degree of the first regulating valve and the opening degree of the second regulating valve.

According to an embodiment of the present disclosure, the controller being configured to determine the target regulating valve from the plurality of regulating valves according to the outlet water temperature, the inlet water temperature, the flow rate, and the heating demand information, further includes: in a case where the heating demand is determined to be not present according to the heating demand information that there is no heating demand, determining each of the first regulating valve and the third regulating valve as the target regulating valve.

According to an embodiment of the present disclosure, the controller being configured to adjust the opening degree of the target regulating valve includes: in a case where the inlet water temperature is less than or equal to a second temperature and this state lasts for a fourth preset duration, reducing an opening degree of the third regulating valve and increasing an opening degree of the first regulating valve; in a state where the inlet water temperature is greater than the second temperature and less than a first temperature, and this state lasts for the fourth preset duration, stopping adjusting the opening degree of the first regulating valve and the opening degree of the third regulating valve.

According to an embodiment of the present disclosure, the above-mentioned circulating water pipeline further includes: an outlet water main pipe section, an inlet of which is in communication with the water outlet of the heat absorption unit, where the first temperature acquisition unit is arranged in the outlet water main pipe section; an inlet water main pipe section, an outlet of which is in communication with the water inlet of the heat absorption unit, where the second temperature acquisition unit and the flow rate measurement unit are both arranged in the inlet water main pipe section, and the temperature-stabilizing water branch pipeline and the cooling water branch pipeline are connected in parallel between an outlet of the outlet water main pipe section and an inlet of the inlet water main pipe section.

According to an embodiment of the present disclosure, the circulating water pipeline includes the temperature stabilizing water branch pipeline and the cooling water branch pipeline, the temperature-stabilizing water branch pipeline and the cooling water branch pipeline are connected in parallel between the water inlet and the water outlet of the heat absorption unit, and the plurality of regulating valves are arranged in the temperature-stabilizing water branch pipeline and the cooling water branch pipeline respectively. Therefore, in a case where the controller adjusts the opening degrees of the plurality of regulating valves according to the outlet water temperature, the inlet water temperature, the flow rate, and the heating demand information, a ratio of circulating cooling water entering the temperature-stabilizing water branch pipeline to circulating cooling water entering the cooling water branch pipeline can be adjusted. Therefore, the cooling water branch pipeline may be used to quickly dissipate heat of the circulating cooling water flowing into the cooling water branch pipeline, and the temperature stabilizing water branch pipeline is used to directly transmit the circulating cooling water flowing into the temperature stabilizing water branch pipeline, so that after the circulating cooling water that has undergone heat dissipation and the circulating cooling water that is directly transmitted are mixed at the water inlet of the heat absorption unit, the inlet water temperature at the water inlet will not deviate too much from a user's preset temperature range, and the inlet water temperature at the water inlet can be adjusted to the user's preset temperature range more quickly.

### BRIEF DESCRIPTION OF DRAWINGS

The above contents and other purposes, features and advantages of the present disclosure will become clear through the following description of the embodiments of the present disclosure with reference to the accompanying drawings.

FIG. 1 schematically shows a schematic structural diagram of a heat dissipation regulation system according to an embodiment of the present disclosure.

FIG. 2 schematically shows a schematic structural diagram of a heat dissipation regulation system according to another embodiment of the present disclosure.

FIG. 3 schematically shows a structural diagram of a heat dissipation regulation system in a case where a second regulating valve and a third regulating valve are determined as target regulating valves according to an embodiment of the present disclosure.

FIG. 4 schematically shows a structural diagram of a heat dissipation regulation system in a case where a first regulating valve and a second regulating valve are determined as target regulating valves according to an embodiment of the present disclosure.

FIG. 5 schematically shows a structural diagram of a heat dissipation regulation system in a case where a first regulating valve and a third regulating valve are determined as target regulating valves according to an embodiment of the present disclosure.

### DESCRIPTION OF EMBODIMENTS

Exemplary embodiments of the present disclosure are described below with reference to the accompanying drawings, in which various details of embodiments of the present disclosure are included to facilitate understanding, and the exemplary embodiments shall be considered merely exemplary. Therefore, it should be recognized by those of ordinary skill in the art that various changes and modifications may be made to the embodiments described herein without departing from the scope and spirit of the present disclosure. Similarly, for clarity and conciseness, descriptions of well-known functions and structures are omitted in the following description. It should be noted that throughout the accompanying drawings, the same elements are represented by the same or similar reference numerals.

In a case where data centers are equipped with large or numerous of network devices for data processing and storage, the data centers will generate a lot of heat. In a case of large temperature difference in the environment where the data centers are located, the operation stability of respective network devices in the data centers will be affected. Therefore, in order to ensure stable operations of the data centers, it is necessary to dissipate the heat generated by the data centers in time.

In order to at least partially solve the technical problems existing in related technology, embodiments of the present disclosure provide a heat dissipation regulation system, which can be applied to the fields of heat dissipation technology, cloud computing technology and Internet of Things technology.

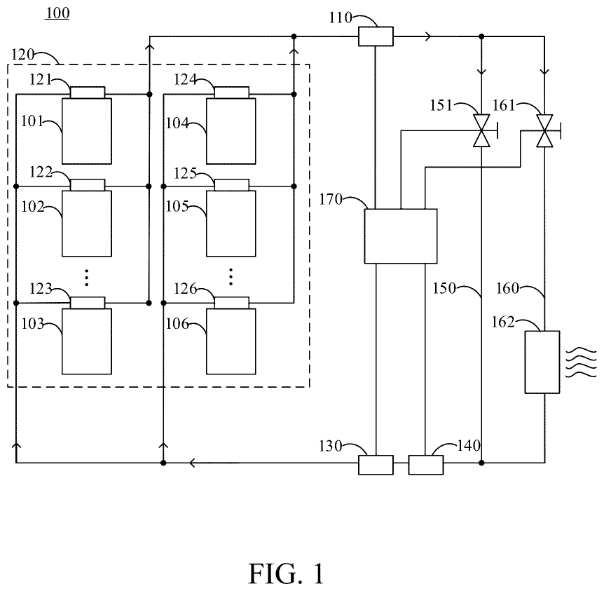

The heat dissipation regulation system of the embodiments of the present disclosure will be described in detail below with reference to FIGS. 1 to 5.

FIG. 1 schematically shows a schematic structural diagram of a heat dissipation regulation system according to an embodiment of the present disclosure.

As shown in FIG. 1, a heat dissipation regulation system 100 of the present embodiment may include a first temperature acquisition unit 110, a heat absorption unit 120, a second temperature acquisition unit 130, a flow rate measurement unit 140, a circulating water pipeline, a plurality of regulating valves, and a controller 170.

According to an embodiment of the present disclosure, the first temperature acquisition unit 110 may be used to collect an outlet water temperature of a water outlet of the heat absorption unit 120. The heat absorption unit 120 may be used to absorb, by using circulating cooling water flowing through the heat absorption unit, heat generated by a heat dissipation device.

According to an embodiment of the present disclosure, the type of the first temperature acquisition unit 110 may be selected according to actual conditions, and is not limited thereto. For example, the first temperature acquisition unit 110 may be a temperature sensor or a temperature transmitter.

According to an embodiment of the present disclosure, the heat absorption unit 120 may include a plurality of heat absorption subunits, and the plurality of heat absorption subunits may be respectively connected to a plurality of heat dissipation devices, and the plurality of heat absorption subunits correspond one-to-one to the plurality of heat dissipation devices, so that the heat generated by each heat dissipation device corresponding to each heat absorption subunit can be absorbed by utilizing circulating cooling water flowing through each heat absorption subunit.

As shown in FIG. 1, the plurality of heat absorption subunits may include a heat absorption subunit 121, a heat absorption subunit 122, a heat absorption subunit 123, a heat absorption subunit 124, a heat absorption subunit 125, and a heat absorption subunit 126. The plurality of heat dissipation devices may include a heat dissipation device 101, a heat dissipation device 102, a heat dissipation device 103, a heat dissipation device 104, a heat dissipation device 105, and a heat dissipation device 106. In an embodiment of the present disclosure, the heat absorption subunit 121 is used to dissipate heat of the heat dissipation device 101, the heat absorption subunit 122 is used to dissipate heat of the heat dissipation device 102, the heat absorption subunit 123 is used to dissipate heat of the heat dissipation device 103, the heat absorption subunit 124 is used to dissipate heat of the heat dissipation device 104, the heat absorption subunit 125 is used to dissipate heat of the heat dissipation device 105, and the heat absorption subunit 126 is used to dissipate heat of the heat dissipation device 106.

According to an embodiment of the present disclosure, the heat absorption unit 120 may use any heat dissipation form (e.g., contact heat dissipation or anon-contact heat dissipation) to dissipate heat of the heat dissipation device. The type of the heat absorption subunit 120 may be selected according to actual conditions, and is not limited thereto. For example, the heat absorption subunit may include a liquid cooling device, and the liquid cooling device may be, for example, a cold plate device, an immersion device, or a spray device.

According to embodiments of the present disclosure, the type of the heat dissipation device may be selected according to actual conditions, and is not limited thereto. For example, the heat dissipation device can be a cabinet for a data center, which can be, for example, a power cabinet, a monitoring cabinet, a server cabinet, a network cabinet, a storage cabinet, etc. The cabinet can be provided with a memory, a server, a power supply, a switch, a router, etc. In an embodiment of the present disclosure, the server can be, for example, an application server, a server for a distributed system, or a server combined with block chain technology, etc.

According to an embodiment of the present disclosure, the second temperature acquisition unit 130 may be used to collect an inlet water temperature of a water inlet of the heat absorption unit 120.

According to an embodiment of the present disclosure, the type of the second temperature acquisition unit 130 may be selected according to actual conditions, and is not limited thereto. For example, the second temperature acquisition unit 130 can be a temperature sensor or a temperature transmitter.

According to an embodiment of the present disclosure, the flow rate measurement unit 140 may be used to measure flow rate of circulating cooling water flowing into or out of the heat absorption unit 120.

According to an embodiment of the present disclosure, the type of the flow rate measurement unit 140 may be selected according to actual conditions, and is not limited thereto. For example, the flow rate measurement unit 140 can be a flow sensor or a flow transmitter.

According to an embodiment of the present disclosure, the circulating water pipeline may include a temperature-stabilizing water branch pipeline 150 and a cooling water branch pipeline 160. The temperature-stabilizing water branch pipeline 150 and the cooling water branch pipeline 160 are connected in parallel between the water inlet and the water outlet of the heat absorption unit 120.

According to an embodiment of the present disclosure, the cooling water branch pipeline 160 is used to cool the circulating cooling water flowing into the cooling water branch pipeline 160. The temperature-stabilizing water branch pipeline 150 is used to transmit the circulating cooling water flowing into the temperature-stabilizing water branch pipeline 150.

According to an embodiment of the present disclosure, a range of a predetermined temperature may be selected according to actual conditions, and is not limited thereto. For example, the range of the predetermined temperature may be 35° C.±1° C., 35° C.±0.5° C. or 30° C.±1° C.

As shown in FIG. 1, a heat exchange unit 162 may be provided in the cooling water branch pipeline 160, and the heat exchange unit 162 may be used to cool the circulating cooling water in the circulating water pipeline.

According to an embodiment of the present disclosure, the heat exchange unit 162 may be selected according to actual conditions, and is not limited thereto. For example, the heat exchange unit 162 can be a cooling tower, a heat exchanger, or a cooling tower and a heat exchanger.

According to an embodiment of the present disclosure, a plurality of regulating valves may be respectively arranged in the temperature-stabilizing water branch pipeline 150 and the cooling water branch pipeline 160.

As shown in FIG. 1, the plurality of adjusting valves may include a regulating valve 151 and a regulating valve 161. The regulating valve 151 may be arranged in the temperature-stabilizing water branch pipeline 150. The regulating valve 161 may be arranged in the cooling water branch pipeline 160.

According to an embodiment of the present disclosure, by regulating the regulating valve 151 and the regulating valve 161, a ratio of circulating cooling water entering the temperature-stabilizing water branch pipeline 150 to circulating cooling water entering the cooling water branch pipeline 160 can be adjusted.

According to an embodiment of the present disclosure, a controller 170 may be electrically connected to the first temperature acquisition unit 110, the second temperature acquisition unit 130, and the plurality of regulating valves. The controller 170 may be used to adjust opening degrees of the plurality of regulating valves according to outlet water temperature, inlet water temperature, flow rate, and heating demand information.

According to an embodiment of the present disclosure, the heating demand information may be information indicating that a user has a heating demand or information indicating that a user does not have a heating demand.

According to an embodiment of the present disclosure, the controller 170 may communicate with a user terminal, and the user terminal may display buttons corresponding to heating demands. Different buttons may be buttons reflecting whether the user has a heating demand or not. The controller 170 may obtain heating demand information in response to a user's click operation on the heating demand button of the user terminal.

According to an embodiment of the present disclosure, the controller 170 can adjust opening degrees of the regulating valve 151 and the regulating valve 161 according to outlet water temperature, inlet water temperature, flow rate, and heating demand information, thereby adjusting a ratio of circulating cooling water entering the temperature-stabilizing water branch pipeline 150 to circulating cooling water entering the cooling water branch pipeline 160.

According to an embodiment of the present disclosure, the circulating water pipeline includes the temperature-stabilizing water branch pipeline and the cooling water branch pipeline, the temperature-stabilizing water branch pipeline and the cooling water branch pipeline are connected in parallel between the water inlet and the water outlet of the heat absorption unit, and the plurality of regulating valves are arranged in the temperature-stabilizing water branch pipeline and the cooling water branch pipeline respectively. Therefore, in a case where the controller adjusts the opening degrees of the plurality of regulating valves according to the outlet water temperature, the inlet water temperature, the flow rate and the heating demand information, the ratio of the circulating cooling water entering the temperature-stabilizing water branch pipeline to the circulating cooling water entering the cooling water branch pipeline can be adjusted, so that the cooling water branch pipeline may be used to quickly dissipate the heat of the circulating cooling water flowing into the cooling water branch pipeline. Meanwhile, the temperature-stabilizing water branch pipeline is used to directly transmit the circulating cooling water flowing into the temperature-stabilizing water branch pipeline, so that after the circulating cooling water that has undergone heat dissipation and the circulating cooling water that is directly transmitted are mixed at the water inlet of the heat absorption unit, the inlet water temperature at the water inlet will not deviate too much from a user's preset temperature range, and the inlet water temperature of the water inlet can be adjusted to the user's preset temperature range more quickly.

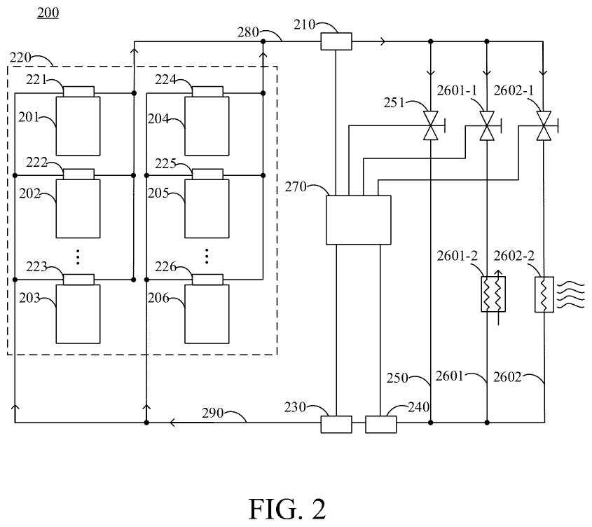

FIG. 2 schematically shows a structural diagram of a heat dissipation regulation system according to another embodiment of the present disclosure.

As shown in FIG. 2, the heat dissipation regulation system 200 of the present embodiment may include a first temperature acquisition unit 210, a heat absorption unit 220, a second temperature acquisition unit 230, a flow rate measurement unit 240, a circulating water pipeline, a plurality of regulating valves, and a controller 270. The circulating water pipeline may include: a temperature-stabilizing water branch pipeline 250 and a cooling water branch pipeline. The first temperature acquisition unit 210, the heat absorption unit 220, the second temperature acquisition unit 230, the flow rate measurement unit 240, the circulating water pipeline, the plurality of regulating valves, and the controller 270 in FIG. 2 are similar to the first temperature acquisition unit 110, the heat absorption unit 120, the second temperature acquisition unit 130, the flow rate measurement unit 140, the circulating water pipeline, the plurality of regulating valves, and the controller 170 in FIG. 1, respectively, in terms of connection relationships and functions.

The heat dissipation regulation system 200 may also include a heat exchange unit arranged in the cooling water branch pipeline for recovering heat absorbed by the heat absorption unit. The heat exchange unit in FIG. 2 is similar to the heat exchange unit 162 in FIG. 1 in terms of connection relationships and functions.

The cooling water branch pipeline may include: a first cooling water branch pipeline 2601 and a second cooling water branch pipeline 2602. The heat exchange unit may include: a heat exchanger 2601-2 arranged in the first cooling water branch pipeline 2601 and a dry cooler 2602-2 arranged in the second cooling water branch pipeline 2602.

According to an embodiment of the present disclosure, the dry cooler 2602-2 may cool circulating cooling water flowing into the second cooling water branch pipeline 2602 in a case where the heat exchanger 2601-2 is not working or a maximum heat dissipation of the heat exchanger 2601-2 is less than the heat generated by the heat dissipation devices 201 to 206.

As shown in FIG. 2, the plurality of regulating valves may include: a first regulating valve 251 arranged in the temperature-stabilizing water branch pipeline 250, a second regulating valve 2601-1 arranged in the first cooling water branch pipeline 2601, and a third regulating valve 2602-1 arranged in the second cooling water branch pipeline 2602.

According to an embodiment of the present disclosure, in a case where the temperature-stabilizing water branch pipeline 250, the first cooling water branch pipeline 2601 and the second cooling water branch pipeline 2602 are connected in parallel between the water inlet and the water outlet of the heat absorption unit 220, the controller may be utilized to adjust opening degrees of the three branch pipelines respectively using the regulating valves arranged in the temperature-stabilizing water branch pipeline 250, the first cooling water branch pipeline 2601 and the second cooling water branch pipeline 2602 respectively, so as to adjust flow rate of circulating cooling water flowing into each of the three branch pipelines. Since the heat exchanger is arranged in the first cooling water branch pipeline 2601, circulating cooling water may be water-cooled for heat dissipation, and since the dry cooler is arranged in the second cooling water branch pipeline, circulating cooling water can be air-cooled for heat dissipation, thereby realizing the use of two cooling water branch pipelines with different cooling modes to dissipate heat of circulating cooling water, such that different heat dissipation modes can be flexibly selected for different application scenarios. As a result, the inlet water temperature of the heat absorption unit 220 can be accurately and quickly regulated to allow the inlet water temperature of the water inlet to be quickly adjusted to within the temperature range predetermined by the user.

As shown in FIG. 2, the circulating water pipeline may further include: an outlet water main pipe section 280 and an inlet water main pipe section 290.

In FIG. 2, an inlet of the outlet main pipe section 280 may be communicated with a water outlet of the heat absorption unit 220. The first temperature acquisition unit 210 may be arranged in the outlet main pipe section 280. An outlet of the inlet main pipe section 290 may be communicated with a water inlet of the heat absorption unit 220. The second temperature acquisition unit 230 and the flow rate measurement unit 240 may both be arranged in the inlet main pipe section 290. The temperature-stabilizing water branch line 250 and the cooling water branch line are connected in parallel between the outlet of the outlet main pipe section 280 and the inlet of the inlet main pipe section 290.

For example, in FIG. 2, the temperature-stabilizing water branch pipeline 250, the first cooling water branch pipeline 2601, and the second cooling water branch pipeline 2602 are connected in parallel between the outlet of the outlet water main pipe section 280 and the inlet of the inlet water main pipe section 290.

According to an embodiment of the present disclosure, the controller being used to adjust opening degrees of the plurality of regulating valves according to outlet water temperature, inlet water temperature, flow rate and heating demand information includes: determining a target regulating valve from the plurality of regulating valves according to outlet water temperature, inlet water temperature, flow rate, and heating demand information sent by the user terminal; closing the regulating valves except the target regulating valve among the plurality of regulating valves; and adjusting an opening degree of the target regulating valve.

For example, in FIG. 2, in a case where the first regulating valve 251 and the second regulating valve 2601-1 are determined as target regulating valves, the third regulating valve 2602-1 may be closed, and opening degrees of the first regulating valve 251 and the second regulating valve 2601-1 may be adjusted. In a case where the first regulating valve 251 and the third regulating valve 2602-1 are determined as target regulating valves, the second regulating valve 2601-1 may be closed, and opening degrees of the first regulating valve 251 and the third regulating valve 2602-1 may be adjusted. In a case where the second regulating valve 2601-1 and the third regulating valve 2602-1 are determined as target regulating valves, the first regulating valve 251 may be closed, and opening degrees of the second regulating valve 2601-1 and the third regulating valve 2602-1 may be adjusted.

According to an embodiment of the present disclosure, the controller being used to determine the target regulating valve from the plurality of regulating valves according to the outlet water temperature, the inlet water temperature, the flow rate and the heating demand information may include: determining flow temperature difference heat according to the outlet water temperature, the inlet water temperature and the flow rate; obtaining a predetermined maximum heat dissipation of the heat exchanger; and in a case where the flow temperature difference heat is greater than or equal to the predetermined maximum heat dissipation and a heating demand is determined to be present according to the heating demand information, determining each of the second regulating valve and the third regulating valve as the target regulating valve.

According to an embodiment of the present disclosure, in a case where the flow temperature difference heat is greater than or equal to the predetermined maximum heat dissipation, and a heating demand is determined to be present according to the heating demand information, it indicates that the user has a heating demand, and the heat dissipation of the heat exchanger cannot completely offset the flow temperature difference heat. Therefore, taking into full consideration the factors of the user's heating demand and the maximum heat dissipation capacity of the heat exchanger, the second regulating valve and the third regulating valve may be determined as target regulating valves. Subsequently, by regulating the target control valves, the heat dissipation of circulating cooling water of the heat exchanger can meet the user's heating demand. Meanwhile, the heat generated by the heat dissipation devices is recovered, and the combined heat dissipation of the heat exchanger and the dry cooler may offset the heat generated by the heat dissipation devices, such that the inlet water temperature is quickly adjusted to be within the user's preset temperature range.

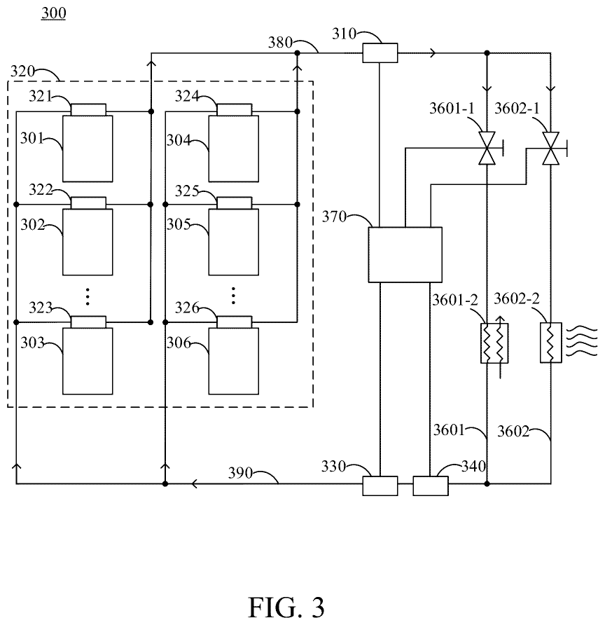

According to an embodiment of the present disclosure, in a case where the second regulating valve and the third regulating valve are determined as target regulating valves, an equivalent structural diagram of the heat dissipation regulation system in FIG. 2 is shown in FIG. 3.

FIG. 3 schematically shows a structural diagram of a heat dissipation regulation system in a case where a second regulating valve and a third regulating valve are determined as target regulating valves according to an embodiment of the present disclosure.

As shown in FIG. 3, a heat dissipation regulation system 300 of the present embodiment may include a first temperature acquisition unit 310, a heat absorption unit 320, a second temperature acquisition unit 330, a flow rate measurement unit 340, a circulating water pipeline, a plurality of regulating valves, and a controller 370. In an embodiment of the present disclosure, the circulating water pipeline may include a cooling water branch pipeline, an outlet water main pipe section 380, and an inlet water main pipe section 390. The cooling water branch pipeline may include: a first cooling water branch pipeline 3601 and a second cooling water branch pipeline 3602. The heat dissipation regulation system 300 may also include a heat exchange unit arranged in the cooling water branch pipeline. The heat exchange unit may include: a heat exchanger 3601-2 arranged in the first cooling water branch pipeline 3601 and a dry cooler 3602-2 arranged in the second cooling water branch pipeline 3602. The plurality of regulating valves may include a second regulating valve 3601-1 arranged in the first cooling water branch pipeline 3601 and a third regulating valve 3602-1 arranged in the second cooling water branch pipeline 3602.

According to an embodiment of the present disclosure, the heat dissipation regulation system 300 in FIG. 3 is substantially similar to the heat dissipation regulation system 200 in FIG. 2 in terms of structure and connection relationship between structures, except that the circulating water pipeline in FIG. 3 does not include a temperature-stabilizing water branch pipeline.

According to the structure of the heat dissipation regulation system 300 in FIG. 3, a specific method by which the controller 370 adjusts opening degrees of target regulating valves in a case where the second regulating valve 3601-1 and the third regulating valve 3602-1 are determined as target regulating valves will be described in detail below.

According to an embodiment of the present disclosure, in a case where the second regulating valve 3601-1 and the third regulating valve 3602-1 are determined as target regulating valves, initial states of respective regulating valves are that: an opening degree of the second regulating valve 3601-1 is adjusted to the maximum, an opening degree of the third regulating valve 3602-1 is 0, and an opening degree of the first regulating valve 251 is 0. At this point, the dry cooler 3602-2 operates at an initial operating frequency.

According to an embodiment of the present disclosure, the controller 370 being used to adjust the opening degree of the target regulating valve includes: in a case where an inlet water temperature is greater than a target inlet water temperature, reducing the opening degree of the second regulating valve 3601-1 and increasing the opening degree of the third regulating valve 3602-1; in a case where the inlet water temperature is less than a first temperature and this state lasts for a first preset duration, stopping adjusting the opening degree of the second regulating valve 3601-1 and the opening degree of the third regulating valve 3602-1, where the first temperature is equal to the sum of the target inlet water temperature and a first preset value.

According to an embodiment of the present disclosure, the target inlet water temperature is an ideal inlet water temperature.

According to an embodiment of the present disclosure, in order to ensure a stable operation of the heat dissipation device and prevent the temperature of the heat dissipation device from being too high, the temperature of the circulating cooling water flowing into the heat absorption unit needs to be lower than a predetermined first temperature.

According to an embodiment of the present disclosure, the target inlet water temperature, the first preset value and the first preset duration may be selected according to actual conditions, and are not limited thereto.

For example, the target inlet water temperature may be 25° C., 30° C., or 35° C., etc. The first preset value may be 1° C. or 0.5° C., etc. The first preset duration may be 5 s, 10 s, or 30 s, etc.

According to an embodiment of the present disclosure, the opening degree of the second regulating valve 3601-1 may be reduced and the opening degree of the third regulating valve 3602-1 may be increased according to a first predetermined opening degree proportion.

According to an embodiment of the present disclosure, the first predetermined opening degree proportion may be selected according to actual conditions, and is not limited thereto. For example, the first predetermined opening degree proportion can be 5%, 10% or 15%.

For example, in the case where the target inlet water temperature is 35° C., the first preset value is 1° C., and the first preset duration is 10 s, the first temperature is 36° C. In a case where the inlet water temperature is greater than 36° C., the opening degree of the second regulating valve 3601-1 is reduced in steps by 5% opening degree per step, and the opening degree of the third regulating valve 3602-1 is increased in steps by 5% opening degree per step. In the case where the inlet water temperature is less than 36° C. and this state lasts for 10 s, the adjustment of the opening degree of the second regulating valve 3601-1 and the opening degree of the third regulating valve 3602-1 is stopped.

According to an embodiment of the present disclosure, in a case where the inlet water temperature is adjusted to less than 36° C. within the first preset duration, the inlet water temperature will generally remain within a predetermined temperature range of 35° C.±1° C. At this point, it is considered that the inlet water temperature is within the user's predetermined temperature range. Therefore, the adjustment of the opening degree of the second regulating valve 3601-1 and the opening degree of the third regulating valve 3602-1 may be stopped.

According to an embodiment of the present disclosure, in a case where the inlet water temperature is greater than the target inlet water temperature, the controller 370 may gradually and quickly divert the circulating cooling water flowing out of the outlet water main pipe section 380 to the second cooling water branch pipeline 3602 by reducing the opening degree of the second regulating valve 3601-1 and increasing the opening degree of the third regulating valve 3602-1, and use both the heat exchanger 3601-2 provided in the first cooling water branch pipeline 3601 and the dry cooler 3602-2 provided in the second cooling water branch pipeline 3602 to cool the circulating cooling water, thereby accelerating the speed of lowering the inlet water temperature.

According to an embodiment of the present disclosure, the controller 370 being used to adjust the opening degree of the target regulating valve further includes: in a case where the inlet water temperature is greater than or equal to the first temperature and this state lasts for a second preset duration, stopping adjusting the opening degree of the second regulating valve 3601-1 and the opening degree of the third regulating valve 3602-1 and increasing the operating frequency of the dry cooler 3602-2; in a case where the operating frequency of the dry cooler 3602-2 is less than a first predetermined frequency, the inlet water temperature is less than the first temperature, and this state lasts for a second preset duration, stopping adjusting the operating frequency of the dry cooler 3602-2.

According to an embodiment of the present disclosure, the second preset duration may be selected according to actual conditions, and is not limited thereto. For example, the second preset duration may be 5 s, 10 s or 30 s, etc. The second preset duration and the first preset duration may be equal or different.

According to an embodiment of the present disclosure, the first predetermined frequency may be selected according to actual conditions, and is not limited thereto. For example, the first predetermined frequency may be the maximum operating frequency of the dry cooler, or 80% of the maximum operating frequency of the dry cooler, or 90% of the maximum operating frequency of the dry cooler, or 95% of the maximum operating frequency of the dry cooler, etc.

According to an embodiment of the present disclosure, the operating frequency of the dry cooler 3602-2 may be increased according to the first predetermined frequency.

According to an embodiment of the present disclosure, the first predetermined frequency may be selected according to actual conditions, and is not limited thereto. For example, the first predetermined frequency may be 3 Hz, 5 Hz or 6 Hz.

For example, the first temperature may be 36° C., the second preset duration may be 10 s, the first predetermined frequency may be the maximum operating frequency of the dry cooler, and the first predetermined frequency may be 5 HZ. The controller 370 may stop adjusting the opening degree of the second regulating valve 3601-1 and the opening degree of the third regulating valve 3602-1 and increase the operating frequency of the dry cooler 3602-2 in steps by 5 HZ per step in a case where the inlet water temperature is greater than or equal to 36° C. and this state lasts for 10 s; and stop adjusting the operating frequency of the dry cooler 3602-2 in a case where the operating frequency of the dry cooler 3602-2 is less than the maximum operating frequency of the dry cooler, the inlet water temperature is less than 36° C., and this state lasts for 10 s.

According to an embodiment of the present disclosure, in a case where the inlet water temperature is greater than or equal to the first temperature and this state lasts for the second preset duration, it indicates that increasing the opening degree of the third control valve 3602-1 does not result in a noticeable cooling effect on the circulating cooling water. Therefore, the efficiency of the dry cooler 3602-2 in cooling the circulating cooling water flowing into the second cooling water branch pipeline 3602 may be increased by increasing the operating frequency of the dry cooler 3602-2, so that the circulating cooling water in the second cooling water branch pipeline 3602 may be quickly cooled, thereby shortening the time for adjusting the inlet water temperature to the temperature range predetermined by the user.

According to an embodiment of the present disclosure, the controller 370 being used to adjust the opening degree of the target regulating valve further includes: in a case where the frequency of the dry cooler 3602-2 is greater than or equal to the first predetermined frequency, the inlet water temperature is greater than or equal to the first temperature, and this state lasts for a third preset duration, stopping adjusting the operating frequency of the dry cooler 3602-2, and at the same time, reducing the opening degree of the second regulating valve 3601-1 and increasing the opening degree of the third regulating valve 3602-1. In a case where the inlet water temperature is less than or equal to the second temperature, and this state lasts for a third preset duration, stopping adjusting the opening degree of the second regulating valve 3601-1 and the opening degree of the third regulating valve 3602-1, and reducing the frequency of the dry cooler 3602-2; where the second temperature is equal to the sum of the target inlet water temperature and a second preset value; in a case where the operating frequency of the dry cooler 3602-2 is greater than the second predetermined frequency, the inlet water temperature is greater than the second temperature and less than the first temperature, and this state lasts for a third preset duration, stopping adjusting the operating frequency of the dry cooler 3602-2.

According to an embodiment of the present disclosure, the third preset duration may be selected according to actual conditions, and is not limited thereto. For example, the third preset duration can be 5 s, 10 s or 30 s, etc. In an embodiment of the present disclosure, the third preset duration, the second preset duration and the first preset duration may be equal or may not be equal.

According to an embodiment of the present disclosure, the second preset value may be selected according to actual conditions, and is not limited thereto. For example, the second preset value may be −1° C., −0.5° C. or −1.5° C.

According to an embodiment of the present disclosure, in a case where the frequency of the dry cooler 3602-2 is greater than or equal to the first predetermined frequency, the inlet water temperature is greater than or equal to the first temperature, and this state lasts for the third preset duration, the opening degree of the second regulating valve 3601-1 may be reduced, and the opening degree of the third regulating valve 3602-1 may be increased, according to a second predetermined opening degree proportion.

According to an embodiment of the present disclosure, the second predetermined opening degree proportion may be selected according to actual conditions, and is not limited thereto. For example, the second predetermined opening degree proportion may be 5%, 10% or 15%, etc. In an embodiment of the present disclosure, the first predetermined opening degree proportion and the second predetermined opening degree proportion may be equal or may not be equal.

For example, the opening degree of the second regulating valve 3601-1 may be decreased in steps by 5% per step, and the opening degree of the third regulating valve 3602-1 may be increased in steps by 5% per step.

According to an embodiment of the present disclosure, in a case where the frequency of the dry cooler 3602-2 is greater than or equal to the first predetermined frequency, the inlet water temperature is greater than or equal to the first temperature, and this state lasts for the third preset duration, it indicates that the frequency of the dry cooler 3602-2 has been adjusted to the maximum frequency or close to the maximum frequency. At this point, the efficiency of lowering the inlet water temperature can no longer be improved by increasing the frequency of the dry cooler 3602-2. The flow rate of the circulating cooling water flowing into the second cooling water branch pipeline 3602 may be increased by reducing the opening degree of the second regulating valve 3601-1 and increasing the opening degree of the third regulating valve 3602-1. Then, the dry cooler 3602-2 with a higher frequency may be used to cool the circulating cooling water with an increased flow rate flowing into the second cooling water branch pipeline 3602. This improves the efficiency of cooling the circulating cooling water and shortens the time for adjusting the inlet water temperature to the user's predetermined temperature range.

According to an embodiment of the present disclosure, in order to ensure a stable operation of the heat dissipation device and avoid excessive heat dissipation thereof, the temperature of the circulating cooling water flowing into the heat absorption unit needs to be greater than a predetermined second temperature.

According to an embodiment of the present disclosure, in a case where the inlet water temperature is less than or equal to the second temperature, and this state lasts for the third preset duration, it indicates that the inlet water temperature is lower than a minimum value of the inlet water temperature and is not within the user's predetermined temperature range. At this point, the inlet water temperature needs to be quickly adjusted back to the user's predetermined temperature range. The efficiency of the dry cooler 3602-2 in cooling the circulating cooling water flowing into the second cooling water branch pipeline 3602 may be reduced by stopping adjusting the opening degree of the second regulating valve 3601-1 and the opening degree of the third regulating valve 3602-1 and reducing the frequency of the dry cooler 3602-2, such that the inlet water temperature is quickly increased.

According to an embodiment of the present disclosure, a second predetermined frequency represents an initial operating frequency of the dry cooler. The second predetermined frequency may be selected according to actual conditions, and is not limited thereto. For example, the second predetermined frequency may be 20 Hz or 25 Hz.

According to an embodiment of the present disclosure, in a case where the operating frequency of the dry cooler 3602-2 is greater than the second predetermined frequency, the inlet water temperature is greater than the second temperature and less than the first temperature, and this state lasts for the third preset duration, it indicates that the inlet water temperature is within the user's preset temperature range and the operating frequency of the dry cooler 3602-2 is greater than the initial operating frequency. Therefore, the adjustment of the operating frequency of the dry cooler 3602-2 can be stopped, so that the heat dissipation regulation system maintains this state and the inlet water temperature remains within the user's predetermined temperature range.

According to an embodiment of the present disclosure, the controller 370 being used to adjust the opening degree of the target regulating valve further includes: in a case where the operating frequency of the dry cooler 3602-2 is equal to the second predetermined frequency, the inlet water temperature is greater than or equal to the first temperature, and this state lasts for a fifth preset duration, performing an operation of adjusting target regulating valves in the case where the second regulating valve 3601-1 and the third regulating valve 3602-1 are determined as the target regulating valves. This realizes the adjustment of the target regulating valves and the operating frequency of the dry cooler 3602-2 by circulation, and the inlet water temperature is thus maintained within the user's predetermined temperature range.

According to an embodiment of the present disclosure, the fifth preset duration may be selected according to actual conditions, and is not limited thereto. For example, the fifth preset duration can be 5 s, 10 s or 30 s, etc. In an embodiment of the present disclosure, the fifth preset duration, the third preset duration, the second preset duration and the first preset duration may be equal or may not be equal.

According to an embodiment of the present disclosure, in a case where the second regulating valve 3601-1 and the third regulating valve 3602-1 are determined as target regulating valves, and respective regulating valves and the dry cooler 3602-2 are in initial states, the controller 370 being used to adjust the opening degree of the target regulating valve includes: in a case where the inlet water temperature is equal to a target inlet water temperature and this state lasts for a sixth preset duration, closing the dry cooler 3602-2 to reduce energy consumption; in a case where the inlet water temperature is greater than the target inlet water temperature, opening the dry cooler 3602-2, and adjusting the operating frequency of the dry cooler 3602-2 to an initial operating frequency, and performing an operation of adjusting target regulating valves in a case where the second regulating valve 3601-1 and the third regulating valve 3602-1 are determined as the target regulating valves.

According to an embodiment of the present disclosure, the sixth preset duration may be selected according to actual conditions, and is not limited thereto. For example, the sixth preset duration can be 5 min or 10 min.

According to an embodiment of the present disclosure, the controller being used to determine target regulating valves from plurality of regulating valves according to the outlet water temperature, the inlet water temperature, the flow rate and the heating demand information further includes: in a case where the flow temperature difference heat is less than a predetermined maximum heat dissipation, and a heating demand is determined to be present according to the heating demand information, determining the first regulating valve and the second regulating valve as target regulating valves.

According to an embodiment of the present disclosure, in a case where the flow temperature difference heat is less than a predetermined maximum heat dissipation and a heating demand is determined to be present according to the heating demand information, it indicates that the user has heating demand, the heat dissipation of the heat exchanger may offset the flow temperature difference heat, and the inlet water temperature of the heat absorption unit may be controlled within the user's predetermined temperature range only by using the heat exchanger. Therefore, taking into full consideration the factors of user's heating demand and the maximum heat dissipation capacity of the heat exchanger, the first control valve and the second control valve may be determined as the target control valves, so that the heat dissipation amount of the circulating cooling water by the heat exchanger can meet the user's heating demand through subsequent regulation and control of the target regulating valves, and at the same time, heat generated by the heat dissipation device is recovered, and heat generated by the heat dissipation device can also be offset. The inlet water temperature is quickly adjusted within the temperature range predetermined by user, which greatly reduces the energy consumption required for heat dissipation of circulating cooling water.

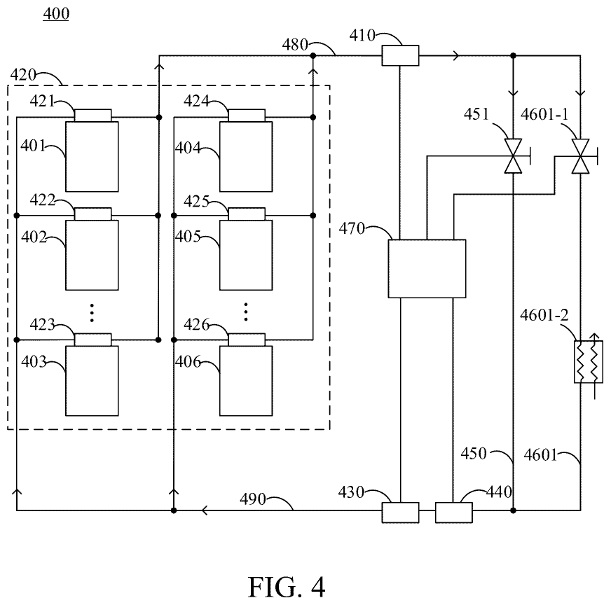

According to an embodiment of the present disclosure, in a case where the first regulating valve and the second regulating valve are determined as target regulating valves, an equivalent structural diagram of the heat dissipation regulation system in FIG. 2 is shown in FIG. 4.

FIG. 4 schematically shows a structural diagram of a heat dissipation regulation system in a case where the first regulating valve and the second regulating valve are determined as target regulating valves according to an embodiment of the present disclosure.

As shown in FIG. 4, the heat dissipation regulation system 400 of the present embodiment may include a first temperature acquisition unit 410, a heat absorption unit 420, a second temperature acquisition unit 430, a flow rate measurement unit 440, a circulating water pipeline, a plurality of regulating valves, and a controller 470. In an embodiment of the present disclosure, the circulating water pipeline may include a cooling water branch pipeline, an outlet water main pipe section 480, and an inlet water main pipe section 490. The cooling water branch pipeline may include a first cooling water branch pipeline 4601. The heat dissipation regulation system 400 may also include a heat exchange unit arranged in the cooling water branch pipeline. The heat exchange unit may include a heat exchanger 4601-2 arranged in the first cooling water branch pipeline 4601. The plurality of regulating valves may include a first regulating valve 451 arranged in the temperature-stabilizing water branch pipeline 450 and a second regulating valve 4601-1 arranged in the first cooling water branch pipeline 4601.

According to an embodiment of the present disclosure, the heat dissipation regulation system 400 in FIG. 4 is substantially similar to the heat dissipation regulation system 200 in FIG. 2 in structure and connection relationship between structures, except that the cooling water branch pipeline in FIG. 4 does not include a second cooling water branch pipeline.

According to the structure of the heat dissipation regulation system 400 in FIG. 4, a specific method by which the controller 370 adjusts opening degrees of target regulating valves in a case where the first regulating valve 451 and the second regulating valve 4601-1 are determined as the target regulating valves will be described in detail below.

According to an embodiment of the present disclosure, in a case where the first regulating valve 451 and the second regulating valve 4601-1 are determined as target regulating valves, initial states of respective regulating valves are that: an opening degree of the second regulating valve 4601-1 is adjusted to the maximum, an opening degree of the third regulating valve is 0, and an opening degree of the first regulating valve 451 is 0. At this point, the dry cooler is not running.

According to an embodiment of the present disclosure, the controller 470 being used to adjust opening degrees of target regulating valves includes: in a case where the inlet water temperature is less than or equal to a second temperature and this state lasts for a fourth preset duration, reducing the opening degree of the second regulating valve 4601-1 and increasing the opening degree of the first regulating valve 451; in a case where the inlet water temperature is greater than the second temperature and less than the first temperature and this state lasts for a fourth preset duration, stopping adjusting the opening degree of the first regulating valve 451 and the opening degree of the second regulating valve 4601-1.

According to an embodiment of the present disclosure, the second temperature is equal to the sum of a target inlet water temperature and a second preset value. The first temperature is equal to the sum of the target inlet water temperature and a first preset value. In an embodiment of the present disclosure, the first preset value is greater than the second preset value.

According to an embodiment of the present disclosure, the target inlet water temperature is an ideal inlet water temperature.

According to an embodiment of the present disclosure, in order to ensure a stable operation of the heat dissipation device and prevent its temperature from being too high, the temperature of the circulating cooling water flowing into the heat absorption unit needs to be lower than the predetermined first temperature.

According to an embodiment of the present disclosure, in order to ensure a stable operation of the heat dissipation device and avoid excessive heat dissipation thereof, the temperature of the circulating cooling water flowing into the heat absorption unit needs to be greater than the predetermined second temperature.

For example, the target temperature may be 25° C., 30° C., or 35° C., etc. The first preset value may be 1° C. or 0.5° C., etc. The second preset value may be −1° C., −0.5° C., or −1.5° C. Therefore, the second temperature may be 29° C. or 34° C., etc., and the first temperature may be 31° C. or 36° C., etc.

According to an embodiment of the present disclosure, in a case where the inlet water temperature is less than or equal to the second temperature and this state lasts for a fourth preset duration, the opening degree of the second regulating valve 4601-1 may be reduced, and the opening degree of the first regulating valve 451 may be increased, according to a third predetermined opening degree proportion.

According to an embodiment of the present disclosure, the third predetermined opening degree proportion may be selected according to actual conditions, and is not limited thereto. For example, the third predetermined opening degree proportion can be 5%, 10% or 15%, etc. In an embodiment of the present disclosure, the third predetermined opening degree proportion, the first predetermined opening degree proportion and the second predetermined opening degree proportion may be equal or may not be equal.

For example, the opening degree of the second regulating valve 3601-1 may be decreased in steps by 5% opening degree per step, and the opening degree of the first regulating valve 451 may be increased in steps by 5% opening degree per step.

According to an embodiment of the present disclosure, in a case where the inlet water temperature is less than or equal to the second temperature and this state lasts for the fourth preset duration, it indicates that the inlet water temperature is lower than the minimum value of the inlet water temperature and is not within the user's predetermined temperature range. At this point, the inlet water temperature needs to be quickly adjusted back to the user's predetermined temperature range. Therefore, the opening degree of the second regulating valve 4601-1 may be reduced and the opening degree of the first regulating valve 451 may be increased to reduce the circulating cooling water flowing into the first cooling water branch pipeline 4601, and reduce the heat dissipation of the circulating cooling water by the heat exchanger 4601-2, and at the same time, the temperature-stabilizing water branch pipeline 450 may be used to directly transmit part of the circulating cooling water to the water inlet of the inlet water main pipe section 490, so that the inlet water temperature rises rapidly and the inlet water temperature quickly reaches the user's predetermined temperature range.

According to an embodiment of the present disclosure, the controller 470 is used to adjust the opening degree of the target regulating valve includes: in a case where the opening degree of the first regulating valve 451 is not 0, the inlet water temperature is greater than or equal to the first temperature, and this state lasts for the fourth preset duration, increasing the opening degree of the second regulating valve 4601-1 and reducing the opening degree of the first regulating valve 451 until the inlet water temperature is lower than the first temperature, so as to cause the heat exchanger 4601-2 to cool a larger flow of circulating cooling water flowing into the first cooling water branch pipeline 4601, thereby improving the efficiency of cooling the circulating cooling water and shortening the time for adjusting the inlet water temperature to the user's predetermined temperature range.

According to an embodiment of the present disclosure, the controller being used to determine a target regulating valve from plurality of regulating valves according to outlet water temperature, inlet water temperature, flow rate and heating demand information further includes: in a case where it is determined according to the heating demand information that there is no heating demand, determining the first regulating valve and the third regulating valve as target regulating valves.

According to an embodiment of the present disclosure, in a case where it is determined that there is no heating demand according to the heating demand information, it indicates that the user has no heating demand and there is no need to use the heat exchanger to dissipate heat of the circulating cooling water. Therefore, taking into full consideration the user's heating demand, the first regulating valve and the third regulating valve may be determined as the target regulating valves. By regulating the first regulating valve and the third regulating valve, the heat dissipation of the circulating cooling water by the dry cooler can offset heat generated by the heat dissipation device, and the inlet water temperature can be quickly adjusted within the user's predetermined temperature range.

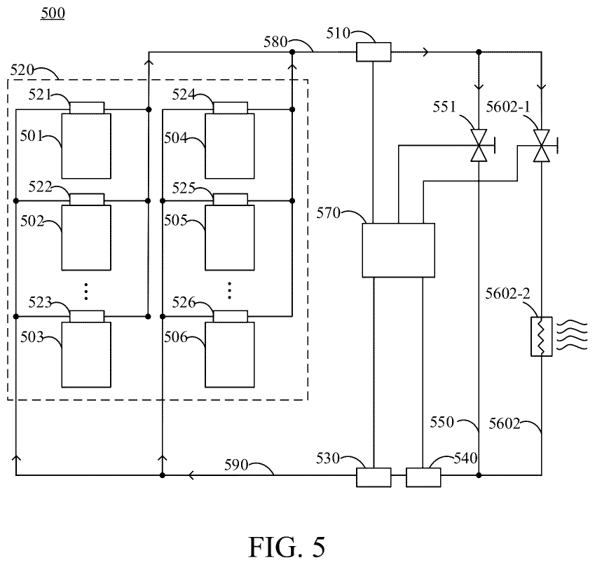

According to an embodiment of the present disclosure, in a case where the first regulating valve and the third regulating valve are determined as target regulating valves, an equivalent structural diagram of the heat dissipation regulating system in FIG. 2 is shown in FIG. 5.

FIG. 5 schematically shows a structural diagram of a heat dissipation regulation system in a case where a first regulating valve and a third regulating valve are determined as target regulating valves according to an embodiment of the present disclosure.

As shown in FIG. 5, a heat dissipation regulation system 500 of the present embodiment may include a first temperature acquisition unit 510, a heat absorption unit 520, a second temperature acquisition unit 530, a flow rate measurement unit 540, a circulating water pipeline, a plurality of regulating valves, and a controller 570. In an embodiment of the present disclosure, the circulating water pipeline may include a cooling water branch pipeline, an outlet water main pipe section 580, and an inlet water main pipe section 590. The cooling water branch pipeline may include a second cooling water branch pipeline 5602. The heat dissipation regulation system 500 may also include a heat exchange unit arranged in the cooling water branch pipeline. The heat exchange unit may include a dry cooler 5602-2 arranged in the second cooling water branch pipeline 5602. The plurality of regulating valves may include a first regulating valve 551 arranged in the temperature-stabilizing water branch pipeline 550 and a third regulating valve 5602-1 arranged in the second cooling water branch pipeline 5602.

According to an embodiment of the present disclosure, the heat dissipation regulation system 500 in FIG. 5 is substantially similar to the heat dissipation regulation system 200 in FIG. 2 in structure and connection relationship between structures, except that the cooling water branch pipeline in FIG. 5 does not include a first cooling water branch pipeline.

According to the structure of the heat dissipation regulation system 500 in FIG. 5, a specific method by which the controller 570 adjusts opening degrees of target regulating valves in a case where the first regulating valve 551 and the third regulating valve 5602-1 are determined as target regulating valves will be described in detail below.

According to an embodiment of the present disclosure, in a case where the first regulating valve 551 and the third regulating valve 5602-1 are determined as target regulating valves, initial states of respective regulating valve are that: an opening degree of the third regulating valve 5602-1 is adjusted to the maximum, an opening degree of the second regulating valve is 0, and an opening degree of the first regulating valve 551 is 0. At this point, the dry cooler 5602-2 operates at an initial operating frequency.

According to an embodiment of the present disclosure, the controller 570 being used adjust an opening degree of a target regulating valve includes: in a case where the inlet water temperature is less than or equal to a second temperature and this state lasts for a fourth preset duration, reducing an opening degree of the third regulating valve 5602-1 and increasing an opening degree of the first regulating valve 551; in a case where the inlet water temperature is greater than the second temperature and less than a first temperature, and this state lasts for the fourth preset duration, stopping adjusting the opening degree of the first regulating valve 551 and the opening degree of the third regulating valve 5602-1.

According to an embodiment of the present disclosure, the second temperature is equal to a sum of a target inlet water temperature and a second preset value. The first temperature is equal to a sum of the target inlet water temperature and a first preset value. In an embodiment, the first preset value is greater than the second preset value.

According to an embodiment of the present disclosure, the target inlet water temperature is an ideal inlet water temperature.

According to an embodiment of the present disclosure, in order to ensure a stable operation of the heat dissipation device and prevent its temperature from being too high, the temperature of circulating cooling water flowing into the heat absorption unit needs to be lower than a predetermined first temperature.

According to an embodiment of the present disclosure, in order to ensure a stable operation of the heat dissipation device and avoid excessive heat dissipation thereof, the temperature of circulating cooling water flowing into the heat absorption unit needs to be greater than a predetermined second temperature.

For example, the target inlet water temperature may be 25° C., 30° C., or 35° C., etc. The first preset value may be 1° C. or 0.5° C., etc. The second preset value may be −1° C., −0.5° C., or −1.5° C. Therefore, the second temperature may be 29° C. or 34° C., etc., and the first temperature may be 31° C. or 36° C., etc.

According to an embodiment of the present disclosure, in a case where an inlet water temperature is less than or equal to the second temperature and this state lasts for a fourth preset duration, an opening degree of the third regulating valve 5602-1 may be reduced, and an opening degree of the first regulating valve 551 may be increased, according to a fourth predetermined opening degree proportion.

According to an embodiment of the present disclosure, the fourth predetermined opening degree proportion may be selected according to actual conditions, and is not limited thereto. For example, the fourth predetermined opening degree proportion can be 5%, 10% or 15%, etc. In an embodiment of the present disclosure, the fourth predetermined opening degree proportion, the third predetermined opening degree proportion, the first predetermined opening degree proportion and the second predetermined opening degree proportion may be equal or may not be equal.

For example, the opening degree of the third regulating valve 5602-1 may be decreased in steps by 5% opening degree per step, and the opening degree of the first regulating valve 551 may be increased in steps by 5% opening degree per step.

According to an embodiment of the present disclosure, in a case where an inlet water temperature is less than or equal to the second temperature and this state lasts for the fourth preset duration, it indicates that the inlet water temperature is lower than a minimum value of the inlet water temperature and is not within the user's predetermined temperature range. At this point, the inlet water temperature needs to be quickly adjusted back to the user's predetermined temperature range. Therefore, the opening degree of the third regulating valve 5602-1 may be reduced and the opening degree of the first regulating valve 551 may be increased to reduce circulating cooling water flowing into the second cooling water branch pipeline 5602, and reduce the heat dissipation of circulating cooling water by the dry cooler 5602-2, and at the same time, the temperature-stabilizing water branch pipeline 550 may be used to directly transmit part of circulating cooling water to the water inlet of the inlet water main pipe section 590, so that the inlet water temperature rises rapidly and the inlet water temperature quickly reaches the user's predetermined temperature range.

According to an embodiment of the present disclosure, the controller 470 being used to adjust an opening degree of a target regulating valve includes: in a case where an opening degree of the first regulating valve 451 is not 0, an inlet water temperature is greater than or equal to the first temperature, and this state lasts for the fourth preset duration, increasing an opening degree of the third regulating valve 5602-1 and reducing an opening degree of the first regulating valve 451 until the inlet water temperature is lower than the first temperature, so as to cause the dry cooler 5602-2 to cool a larger flow of circulating cooling water flowing into the second cooling water branch pipeline 5602, thereby improving the efficiency of cooling circulating cooling water and shortening the time for adjusting the inlet water temperature to the user's predetermined temperature range.

It should be understood that the various forms of processes shown above may be used to reorder, add or delete steps. For example, the steps recorded in the present application can be executed in parallel, sequentially or in different orders, as long as the desired results of the technical solution disclosed in this disclosure can be achieved, and the present application is not limited thereto.

The above specific implementations do not constitute a limitation on the protection scope of the present disclosure. It should be understood by those skilled in the art that various modifications, combinations, sub-combinations and substitutions can be made according to design requirements and other factors. Any modification, equivalent substitution and improvement made within the spirit and principle of the present disclosure shall be included in the protection scope of the present disclosure.

What is claimed is:

1. A heat dissipation regulation system, comprising:
a first temperature acquisition unit, configured to collect an outlet water temperature of a water outlet of a heat absorption unit, wherein the heat absorption unit is configured to absorb, by using circulating cooling water flowing through the heat absorption unit, heat generated by a heat dissipation device;
a second temperature acquisition unit, configured to collect an inlet water temperature of a water inlet of the heat absorption unit;
a flow rate measurement unit, configured to measure flow rate of the circulating cooling water flowing into or out of the heat absorption unit;
a circulating water pipeline, comprising:
a temperature-stabilizing water branch pipeline; and
a cooling water branch pipeline;
wherein the temperature-stabilizing water branch pipeline and the cooling water branch pipeline are connected in parallel between the water inlet and the water outlet of the heat absorption unit;
a plurality of regulating valves, arranged in the temperature-stabilizing water branch pipeline and the cooling water branch pipeline, respectively;
a controller, electrically connected with the first temperature acquisition unit, the second temperature acquisition unit, and the plurality of regulating valves, and configured to adjust opening degrees of the plurality of regulating valves according to the outlet water temperature, the inlet water temperature, the flow rate, and heating demand information.

2. The system according to claim 1, wherein the controller being configured to adjust the opening degrees of the plurality of regulating valves according to the outlet water temperature, the inlet water temperature, the flow rate, and the heating demand information, comprises:
determining a target regulating valve from the plurality of regulating valves according to the outlet water temperature, the inlet water temperature, the flow rate, and the heating demand information sent by a user terminal;
closing regulating valves other than the target regulating valve among the plurality of regulating valves; and
adjusting an opening degree of the target regulating valve.

3. The system according to claim 2, further comprising a heat exchange unit arranged in the cooling water branch pipeline, and configured to recover heat absorbed by the heat absorption unit;
wherein the cooling water branch pipeline comprises: a first cooling water branch pipeline and a second cooling water branch pipeline;
the heat exchange unit comprises: a heat exchanger arranged in the first cooling water branch pipeline and a dry cooler arranged in the second cooling water branch pipeline; and
the plurality of regulating valves comprise: a first regulating valve arranged in the temperature-stabilizing water branch pipeline, a second regulating valve arranged in the first cooling water branch pipeline, and a third regulating valve arranged in the second cooling water branch pipeline.

4. The system according to claim 3, wherein the controller being configured to determine the target regulating valve from the plurality of regulating valves according to the outlet water temperature, the inlet water temperature, the flow rate, and the heating demand information, comprises:
determining flow temperature difference heat according to the outlet water temperature, the inlet water temperature, and the flow rate;
obtaining a predetermined maximum heat dissipation of the heat exchanger;
in a case where the flow temperature difference heat is greater than or equal to the predetermined maximum heat dissipation and a heating demand is determined to be present according to the heating demand information, determining each of the second regulating valve and the third regulating valve as the target regulating valve.

5. The system according to claim 4, wherein the controller being configured to adjust the opening degree of the target regulating valve comprises:
in a case where the inlet water temperature is greater than a target inlet water temperature, reducing an opening degree of the second regulating valve and increasing an opening degree of the third regulating valve;
in a case where the inlet water temperature is lower than a first temperature and this state lasts for a first preset duration, stopping adjusting the opening degree of the second regulating valve and the opening degree of the third regulating valve, wherein the first temperature is equal to a sum of the target inlet water temperature and a first preset value.

6. The system according to claim 5, wherein the controller being configured to adjust the opening degree of the target regulating valve further comprises:
in a case where the inlet water temperature is greater than or equal to the first temperature and this state lasts for a second preset duration, stopping adjusting the opening degree of the second regulating valve and the opening degree of the third regulating valve and increasing an operating frequency of the dry cooler;
in a case where the operating frequency of the dry cooler is less than a first predetermined frequency, the inlet water temperature is less than the first temperature, and this state lasts for the second preset duration, stopping adjusting the operating frequency of the dry cooler.

7. The system according to claim 6, wherein the controller being configured to adjust the opening degree of the target regulating valve further comprises:
in a case where the operating frequency of the dry cooler is greater than or equal to the first predetermined frequency, the inlet water temperature is greater than or equal to the first temperature, and this state lasts for a third preset duration, stopping adjusting the operating frequency of the dry cooler, reducing the opening degree of the second regulating valve, and increasing the opening degree of the third regulating valve;
in a case where the inlet water temperature is less than or equal to a second temperature and this state lasts for the third preset duration, stopping adjusting the opening degree of the second regulating valve and the opening degree of the third regulating valve, and reducing the operating frequency of the dry cooler; wherein the second temperature is equal to a sum of the target inlet water temperature and a second preset value;
in a case where the operating frequency of the dry cooler is greater than a second predetermined frequency, the inlet water temperature is greater than the second temperature and less than the first temperature, and this state lasts for the third preset duration, stopping adjusting the operating frequency of the dry cooler.

8. The system according to claim 4, wherein the controller being configured to determine the target regulating valve from the plurality of regulating valves according to the outlet water temperature, the inlet water temperature, the flow rate, and the heating demand information, further comprises:
in a case where the flow temperature difference heat is less than the predetermined maximum heat dissipation, and a heating demand is determined to be present according to the heating demand information, determining each of the first regulating valve and the second regulating valve as the target regulating valve.

9. The system according to claim 8, wherein the controller being configured to adjust the opening degree of the target regulating valve comprises:
in a case where the inlet water temperature is less than or equal to a second temperature and this state lasts for a fourth preset duration, reducing an opening degree of the second regulating valve and increasing an opening degree of the first regulating valve;
in a case where the inlet water temperature is greater than the second temperature and less than a first temperature, and this state lasts for the fourth preset duration, stopping adjusting the opening degree of the first regulating valve and the opening degree of the second regulating valve.

10. The system according to claim 4, wherein the controller being configured to determine the target regulating valve from the plurality of regulating valves according to the outlet water temperature, the inlet water temperature, the flow rate, and the heating demand information, further comprises:
in a case where the heating demand is determined to be not present according to the heating demand information, determining each of the first regulating valve and the third regulating valve as the target regulating valve.

11. The system according to claim 10, wherein the controller being configured to adjust the opening degree of the target regulating valve comprises:
in a case where the inlet water temperature is less than or equal to a second temperature and this state lasts for a fourth preset duration, reducing an opening degree of the third regulating valve and increasing an opening degree of the first regulating valve;
in a case where the inlet water temperature is greater than the second temperature and less than a first temperature, and this state lasts for the fourth preset duration, stopping adjusting the opening degree of the first regulating valve and the opening degree of the third regulating valve.

12. The system according to claim 2, wherein the circulating water pipeline further comprises:
an outlet water main pipe section, an inlet of which is in communication with the water outlet of the heat absorption unit, wherein the first temperature acquisition unit is arranged in the outlet water main pipe section;
an inlet water main pipe section, an outlet of which is in communication with the water inlet of the heat absorption unit, wherein the second temperature acquisition unit and the flow rate measurement unit are both arranged in the inlet water main pipe section, and the temperature-stabilizing water branch pipeline and the cooling water branch pipeline are connected in parallel between an outlet of the outlet water main pipe section and an inlet of the inlet water main pipe section.

13. The system according to claim 3, wherein the controller being configured to adjust the opening degree of the target regulating valve comprises:
in a case where the inlet water temperature is greater than a target inlet water temperature, reducing an opening degree of the second regulating valve and increasing an opening degree of the third regulating valve;
in a case where the inlet water temperature is lower than a first temperature and this state lasts for a first preset duration, stopping adjusting the opening degree of the second regulating valve and the opening degree of the third regulating valve, wherein the first temperature is equal to a sum of the target inlet water temperature and a first preset value.

14. The system according to claim 5, wherein the controller being configured to determine the target regulating valve from the plurality of regulating valves according to the outlet water temperature, the inlet water temperature, the flow rate, and the heating demand information, further comprises:
in a case where the flow temperature difference heat is less than the predetermined maximum heat dissipation, and the heating demand is determined to be present according to the heating demand information, determining each of the first regulating valve and the second regulating valve as the target regulating valve.

15. The system according to claim 6, wherein the controller being configured to determine the target regulating valve from the plurality of regulating valves according to the outlet water temperature, the inlet water temperature, the flow rate, and the heating demand information, further comprises:
in a case where the flow temperature difference heat is less than the predetermined maximum heat dissipation, and the heating demand is determined to be present according to the heating demand information, determining each of the first regulating valve and the second regulating valve as the target regulating valve.

16. The system according to claim 7, wherein the controller being configured to determine the target regulating valve from the plurality of regulating valves according to the outlet water temperature, the inlet water temperature, the flow rate, and the heating demand information, further comprises:
in a case where the flow temperature difference heat is less than the predetermined maximum heat dissipation, and the heating demand is determined to be present according to the heating demand information, determining each of the first regulating valve and the second regulating valve as the target regulating valve.

17. The system according to claim 5, wherein the controller being configured to determine the target regulating valve from the plurality of regulating valves according to the outlet water temperature, the inlet water temperature, the flow rate, and the heating demand information, further comprises:
in a case where the heating demand is determined to be not present according to the heating demand information, determining each of the first regulating valve and the third regulating valve as the target regulating valve.

18. The system according to claim 6, wherein the controller being configured to determine the target regulating valve from the plurality of regulating valves according to the outlet water temperature, the inlet water temperature, the flow rate, and the heating demand information, further comprises:
in a case where the heating demand is determined to be not present according to the heating demand information, determining each of the first regulating valve and the third regulating valve as the target regulating valve.

19. The system according to claim 7, wherein the controller being configured to determine the target regulating valve from the plurality of regulating valves according to the outlet water temperature, the inlet water temperature, the flow rate, and the heating demand information, further comprises:
in a case where the heating demand is determined to be not present according to the heating demand information, determining each of the first regulating valve and the third regulating valve as the target regulating valve.

20. The system according to claim 8, wherein the controller being configured to determine the target regulating valve from the plurality of regulating valves according to the outlet water temperature, the inlet water temperature, the flow rate, and the heating demand information, further comprises:
in a case where the heating demand is determined to be not present according to the heating demand information, determining each of the first regulating valve and the third regulating valve as the target regulating valve.
